(19) United States
(12) Patent Application Publication
(10) Pub. No.: US 2014/0319985 A1
(43) Pub. Date: Oct. 30, 2014

(54) MOVEMENT MECHANISM AND RACK HOUSING STRUCTURE

(71) Applicant: FUJITSU LIMITED, Kawasaki-shi (JP)

(72) Inventors: Akira KIKUCHI, Kawasaki (JP); Eichiro OKUMURA, Kawasaki (JP); Akihiro HAMAGUCHI, Kawasaki (JP); Akira MINEGISHI, Setagaya (JP)

(73) Assignee: FUJITSU LIMITED, Kawasaki-shi (JP)

(21) Appl. No.: 14/244,052

(22) Filed: Apr. 3, 2014

(30) Foreign Application Priority Data
Apr. 26, 2013 (JP) 2013-094666

(51) Int. Cl. H05K 7/20; H05K 7/18

(52) U.S. Cl. CPC H05K 7/20709; H05K 7/183
USPC 312/317.1; 384/26

(57) ABSTRACT

A movement mechanism includes: a guide member; an installation base that is movably provided on the guide member; and a removable cover base that is removably disposed, next to the installation base, on the guide member.

### CROSS-REFERENCE TO RELATED APPLICATION

This application is based upon and claims the benefit of priority of the prior Japanese Patent Application No. 2013-094666, filed on Apr. 26, 2013, the entire contents of which are incorporated herein by reference.

### FIELD

The embodiments discussed herein are related to movement mechanisms and rack housing structures.

### BACKGROUND

A base isolation rack that supports a rack installation base with a slidable support, the rack installation base on which a rack for an electronic device such as a server is installed, is known (see, for example, Japanese Laid-open Patent Publication No. 2002-237690).

Moreover, a solid installation device that is vertically provided with two rack installation bases is known (see, for example, Japanese Laid-open Patent Publication No. 6-282354).

Incidentally, to facilitate movement of a rack, for example, a rack installation base may be movably supported by a guide member such as a guide rail installed on a floor.

However, if the guide member is installed on the floor, the guide member lies in the way when, for example, an operator performs maintenance and so forth of an electronic device, and the operator's workability may be reduced.

### SUMMARY

According to an aspect of the invention, a movement mechanism includes: a guide member; an installation base that is movably provided on the guide member; and a removable cover base that is removably disposed, next to the installation base, on the guide member.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view depicting a container in a first embodiment;

FIG. 2 is a perspective view depicting a process of carrying a rack into the container depicted in FIG. 1;

FIG. 3 is a perspective view depicting a movement mechanism depicted in FIG. 1;

FIG. 4 is a sectional view taken on the line IV-IV of FIG. 3;

FIG. 5 is a side view depicting an installation base depicted in FIG. 3;

FIG. 6A is a cross-sectional view of the container, the cross-sectional view depicting a state in which a front-side removable floor member and a rear-side removable floor member are removed from guide rails;

FIG. 6B is a cross-sectional view of the container, the cross-sectional view depicting a state in which the installation base was moved along the guide rails to the side where a front-side passage is located;

FIG. 6C is a cross-sectional view of the container, the cross-sectional view depicting a state in which the front-side removable floor member and the rear-side removable floor member are attached to the guide rails of a rear-side passage;

FIG. 7 is a cross-sectional view depicting a cooling unit and a container in a second embodiment;

FIG. 8 is a perspective view depicting a partition member depicted in FIG. 7;

FIG. 9 is a plan view depicting the partition member depicted in FIG. 7;

FIG. 10A is a cross-sectional view of the container, the cross-sectional view depicting a state which was before a rack was moved;

FIG. 10B is a cross-sectional view of the container, the cross-sectional view depicting a state in which the rack was moved to the side where the front-side passage is located;

FIG. 10C is a cross-sectional view of the container, the cross-sectional view depicting a state in which the rack was moved to the side where the rear-side passage is located;

FIG. 11 is an enlarged side view depicting a cable guide; and

FIG. 12 is a sectional view corresponding to FIG. 4, the sectional view depicting a modified example of the guide rail.

### DESCRIPTION OF EMBODIMENTS

Hereinafter, a first embodiment will be described.

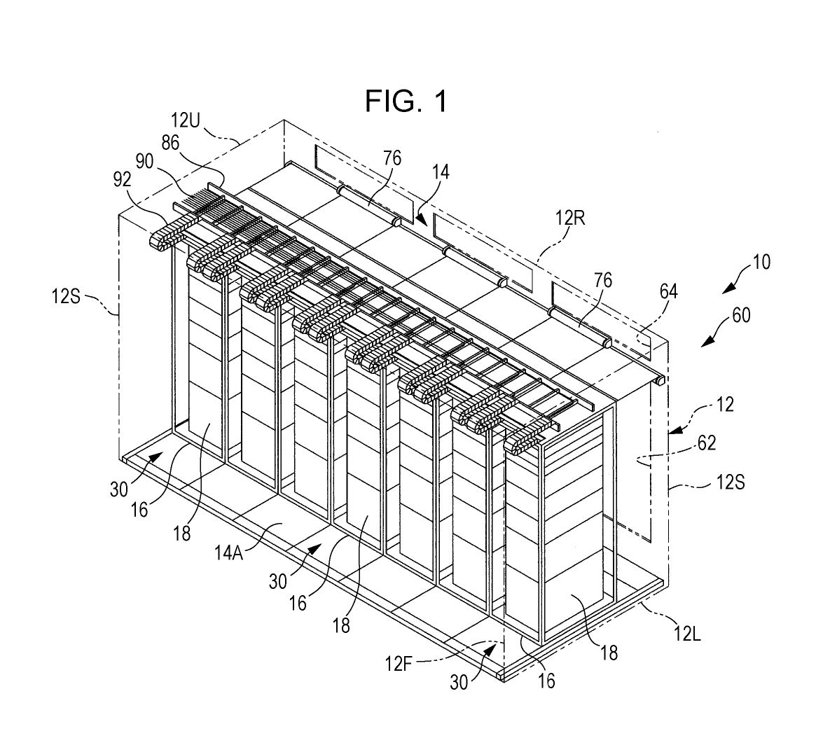

As depicted in FIG. 1, a container-type information processing apparatus (a container-type data center) 10 according to this embodiment includes a container 12, a plurality of racks 16, a plurality of electronic devices 18, and movement mechanisms 30. Moreover, to the container-type information processing apparatus 10, a rack housing structure 60 is applied.

Incidentally, the rack housing structure 60 will be described later in a second embodiment.

The container 12 is formed into a horizontally long box in the shape of a rectangular parallelepiped and has a top wall section 12U, a bottom wall section 12L, a front wall section 12F, a rear wall section 12R, and a pair of side wall sections 12S. Inside the container 12, a rack housing chamber 14 is formed.

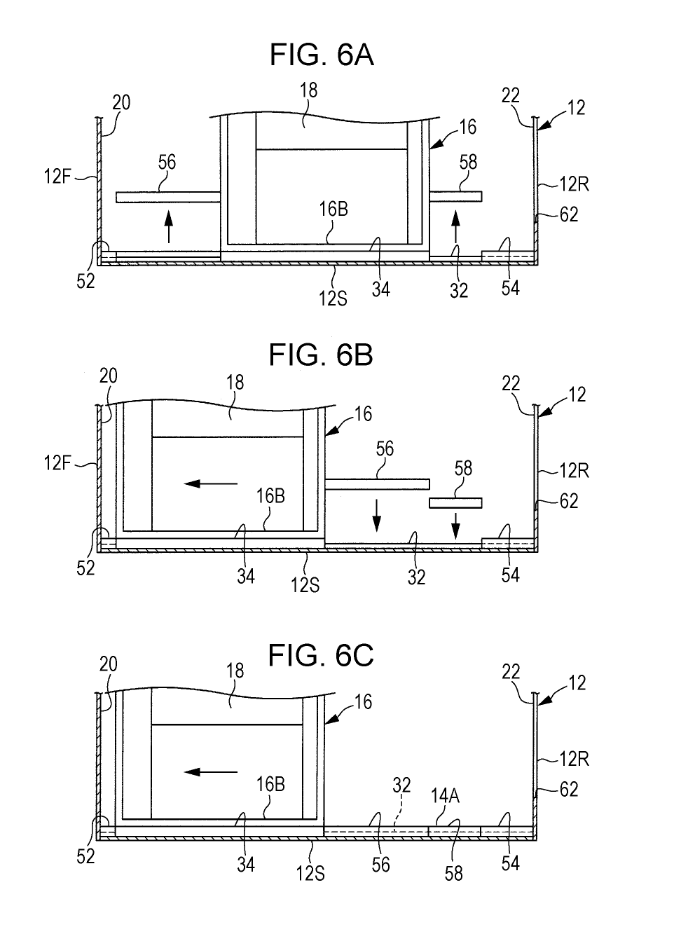

In the rack housing chamber 14, a plurality of (in this embodiment, seven) racks 16 are housed. Each rack 16 is configured as a server rack that houses a plurality of electronic devices 18 such as servers. These racks 16 are arranged in a line in a longitudinal direction of the container 12. Moreover, between the plurality of racks 16 and the front wall section 12F of the container 12, a front-side passage 20 (see FIG. 6A) is formed. Furthermore, between the plurality of racks 16 and the rear wall section 12R of the container 12, a rear-side passage 22 (see FIG. 6A) is formed.

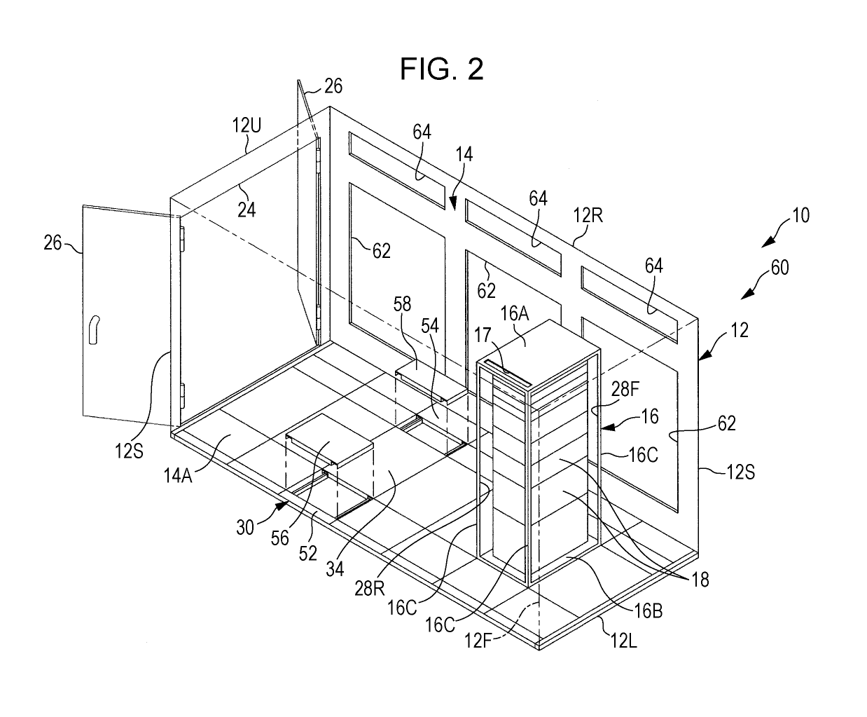

As depicted in FIG. 2, in one side wall section 12S of the container 12, a carry-in entrance 24 through which the racks 16 are carried into the rack housing chamber 14 is formed. To this side wall section 12S, a pair of doors 26 by which the carry-in entrance 24 is opened and closed is attached.

Each rack 16 is formed into a horizontally long rectangular parallelepiped and has a top plate 16A, a bottom plate 16B, and four supporting columns 16C. The supporting columns 16C are erected at the corners of the bottom plate 16B and support the top plate 16A. Incidentally, in the rack 16, a plurality of rails for mounting devices are attached to unillustrated columns (mount angles) for mounting devices, the columns on which the electronic devices 18 are installed. Moreover, in the top plate 16A, a cable opening 17 through which a cable 90, which will be described later, is placed is formed.

In a front side of the rack 16, a front-side opening 28F is formed. Moreover, in a rear side of the rack 16, a rear-side opening 28R is formed. Each rack 16 is disposed in such a way that the rear-side opening 28R faces the front wall section 12F of the container 12. This makes it possible to operate the electronic devices 18 and replace the parts thereof through the rear-side opening 28R from the front-side passage 20. Likewise, it is possible to operate the electronic devices 18 and replace the parts thereof through the front-side opening 28F from the rear-side passage 22. Incidentally, a door by which the front-side opening 28F is opened and closed may be provided in the rack 16, and a door by which the rear-side opening 28R is opened and closed may be provided in the rack 16.

In the bottom wall section 12L of the container 12, a plurality of (in this embodiment, seven) movement mechanisms 30 are provided. The plurality of movement mechanisms 30 movably support the racks 16 and form a floor section 14A of the rack housing chamber 14.

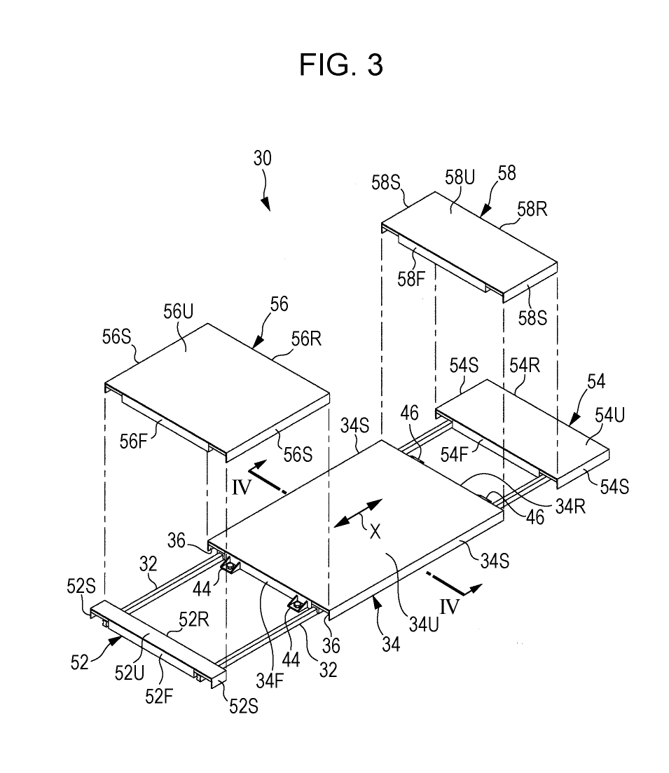

Specifically, as depicted in FIG. 3, each movement mechanism 30 includes a pair of guide rails 32, an installation base 34, a pair of a front-side fixed floor member 52 and a rear-side fixed floor member 54, and a pair of a front-side removable floor member 56 and a rear-side removable floor member 58. Incidentally, the guide rail 32 is an example of a guide member. Moreover, the front-side fixed floor member 52 and the rear-side fixed floor member 54 are examples of a fixed floor member and are examples of a stopper section. Furthermore, the front-side removable floor member 56 and the rear-side removable floor member 58 are examples of a removable floor member and are examples of a removable cover base.

The pair of guide rails 32 is disposed in such a way that the guide rails 32 face each other and are parallel to each other. On the pair of guide rails 32, the installation base 34 on which the rack 16 is installed is movably provided. The installation base 34 is disposed on the pair of guide rails 32 and covers the pair of guide rails 32 from above.

The installation base 34 is formed of a steel sheet or the like into a rectangular shape in a plan view and has a placement section 34U, a front wall section 34F, a rear wall section 34R, and a pair of side wall sections 34S. The placement section 34U is formed into a panel and is formed to have the same size as the bottom plate 16B of the rack 16. On the placement section 34U, the rack 16 is placed.

In the front wall section 34F, a pair of front-side brackets 44 is provided. Likewise, in the rear wall section 34R of the installation base 34, a pair of rear-side brackets 46 is provided. Furthermore, in the front wall section 34F and the rear wall section 34R, notch sections 36 through which the pair of guide rails 32 is inserted are formed.

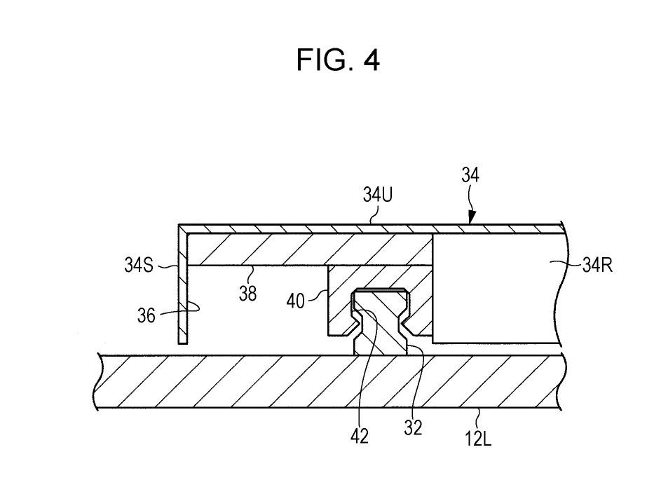

As depicted in FIG. 4, on each side of the placement section 34U in the under surface thereof, a sliding member (slider) 40 is provided with a reinforcing panel 38 placed between the under surface and the sliding member 40. In the under surface of the sliding member 40, an engaging groove 42 in which the guide rail 32 slidably engages is formed. By engaging the guide rails 32 in the engaging grooves 42 (by bringing the guide rails 32 into engagement with the engaging grooves 42), the installation base 34 is movably supported along the guide rails 32.

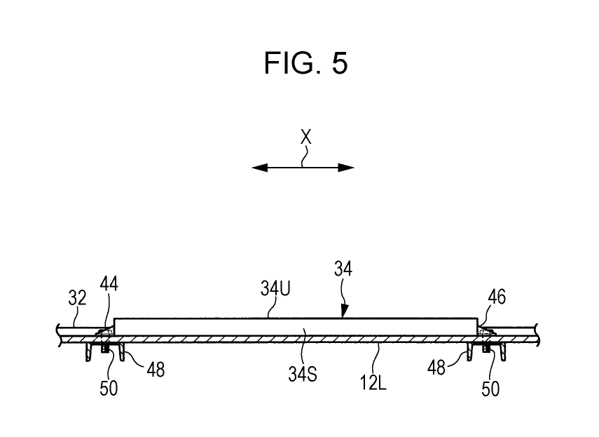

As depicted in FIG. 5, in the under surface of the bottom wall section 12L of the container 12, a pair of fixing frames 48 extending in a direction intersecting a movement direction (an arrow X direction) of the installation base 34 is provided. Each of the pair of fixing frames 48 is formed into the shape of the letter C in cross section with an opening in a lower part thereof. As a result of the front-side brackets 44 and the rear-side brackets 46 being fixed to the pair of fixing frames 48 with bolts 50, the installation base 34 is fixed to the bottom wall section 12L of the container 12. Incidentally, in the following description, the position in which the installation base 34 is fixed to the container 12 is assumed to be a fixation position (an initial position) of the installation base 34.

As depicted in FIG. 3, on both sides in the movement direction (the arrow X direction) of the installation base 34, the front-side fixed floor member 52 and the rear-side fixed floor member 54 are disposed. The front-side fixed floor member 52 and the rear-side fixed floor member 54 are formed of a steel sheet or the like into a rectangular shape in a plan view. The front-side fixed floor member 52 and the rear-side fixed floor member 54 respectively have top face sections 52U and 54U, front wall sections 52F and 54F, rear wall sections 52R and 54R, and a pair of side wall sections 52S and a pair of side wall sections 54S. The front wall sections 52F and 54F, the rear wall sections 52R and 54R, and the pair of side wall sections 52S and the pair of side wall sections 54S respectively extend downward from the outer regions of the top face sections 52U and 54U and support the top face sections 52U and 54U with respect to the bottom wall section 12L of the container 12.

The front-side fixed floor member 52 is disposed on one end of the pair of guide rails 32 and covers the pair of guide rails 32 from above. The front-side fixed floor member 52 is fixed to the pair of guide rails 32 or the bottom wall section 12L of the container 12 with unillustrated bolts or the like. Moreover, the top face section 52U of the front-side fixed floor member 52 forms the floor section 14A of the rack housing chamber 14 on that side where the front-side passage 20 is located. In addition, when the installation base 34 is moved to the side where the front-side passage 20 is located (see FIG. 6A), as a result of the installation base 34 making contact with the front-side fixed floor member 52, the movement of the installation base 34 is restricted. That is, the front-side fixed floor member 52 keeps the installation base 34 from coming off the one end of the pair of guide rails 32.

The rear-side fixed floor member 54 is disposed on the other end of the pair of guide rails 32 and covers the other end from above. The rear-side fixed floor member 54 is fixed to the pair of guide rails 32 or the bottom wall section 12L of the container 12 with unillustrated bolts or the like. Moreover, the top face section 54U of the rear-side fixed floor member 54 forms the floor section 14A of the rack housing chamber 14 on that side where the rear-side passage 22 is located. In addition, when the installation base 34 is moved to the side where the rear-side passage 22 is located (see FIG. 6A), as a result of the installation base 34 making contact with the rear-side fixed floor member 54, the movement of the installation base 34 is restricted. That is, the rear-side fixed floor member 54 keeps the installation base 34 from coming off the other end of the pair of guide rails 32. Incidentally, in this embodiment, the width of the front-side fixed floor member 52 is smaller than the width of the rear-side fixed floor member 54.

Between the front-side fixed floor member 52 and the installation base 34, the front-side removable floor member 56 is removably disposed (fitted). Likewise, between the rear-side fixed floor member 54 and the installation base 34, the rear-side removable floor member 58 is removably disposed (fitted). The front-side removable floor member 56 and the rear-side removable floor member 58 are formed of a steel sheet or the like into a rectangular shape in a plan view.

The front-side removable floor member 56 and the rear-side removable floor member 58 respectively have top face sections 56U and 58U, front wall sections 56F and 58F, rear wall sections 56R and 58R, and a pair of side wall sections 56S and a pair of side wall sections 58S. The front wall sections 56F and 58F, the rear wall sections 56R and 58R, and the pair of side wall sections 56S and the pair of side wall sections 58S respectively extend downward from the outer regions of the top face sections 56U and 58U and support the top face sections 56U and 58U with respect to the bottom wall section 12L of the container 12.

The front-side removable floor member 56 is disposed on the pair of guide rails 32 and covers the pair of guide rails 32 from above. Likewise, the rear-side removable floor member 58 is disposed on the pair of guide rails 32 and covers the pair of guide rails 32 from above.

The top face sections 56U and 58U of the front-side removable floor member 56 and the rear-side removable floor member 58 form the floor section 14A of the rack housing chamber 14 with the other top face sections 52U and 54U and the placement section 34U. Moreover, the top faces of the top face sections 56U and 58U are disposed in such a way that the top faces of the top face sections 56U and 58U are flush with the top faces of the other top face sections 52U and 54U and the placement section 34U to make the floor section 14A of the rack housing chamber 14 flat. Incidentally, here, “being flush with something” is a concept including not only a structure in which the top faces of the top face sections 52U, 54U, 56U, and 58U and the placement section 34U are disposed in the same plane, but also a structure in which the top faces of the top face sections 52U, 54U, 56U, and 58U and the placement section 34U are slightly off the same plane due to a production error or the like.

Next, a method for moving the rack 16 by the movement mechanism 30 will be described.

First, a method for expanding the rear-side passage 22 by moving the rack 16 to the side where the front-side passage 20 is located will be described. In FIG. 6A, the installation base 34 fixed in the fixation position is depicted. As depicted in FIG. 6A, the front-side removable floor member 56 and the rear-side removable floor member 58 are removed from the pair of guide rails 32 and the front-side brackets 44 and the rear-side brackets 46 (see FIG. 5) of the installation base 34 are exposed to the outside. Next, the bolts 50 (see FIG. 5) are removed from the front-side brackets 44 and the rear-side brackets 46. This allows the installation base 34 to move along the pair of guide rails 32. Incidentally, holes that allow a tool and so forth for the bolts 50 to pass therethrough may be provided in the rear-side removable floor member 58 to make it possible to operate the bolts 50 without removing the rear-side removable floor member 58.

Next, as depicted in FIG. 6B, the installation base 34 is moved along the pair of guide rails 32 to the side where the front-side passage 20 is located and is brought into contact with the front-side fixed floor member 52. That is, the installation base 34 is moved from the fixation position depicted in FIG. 6A to the movement position on one side (the front side) depicted in FIG. 6B. As a result, the rack 16 supported on the installation base 34 moves to the side where the front-side passage 20 is located, and the rear-side passage 22 is expanded.

Next, as depicted in FIG. 6C, the rear-side removable floor member 58 is placed in an original position on the pair of guide rails 32. Next, between the rear-side removable floor member 58 and the installation base 34, the front-side removable floor member 56 is disposed (fitted). As a result, the rear-side removable floor member 58 and the front-side removable floor member 56 form the floor section 14A of the rear-side passage 22 in the rack housing chamber 14.

Moreover, by disposing the rear-side removable floor member 58 and the front-side removable floor member 56 side by side between the installation base 34 and the rear-side fixed floor member 54, the space between the installation base 34 and the rear-side fixed floor member 54 is filled. As a result, the movement of the installation base 34 to the side where the rear-side passage 22 is located is restricted.

Incidentally, when the installation base 34 is returned from the movement position to the fixation position, the above procedure is performed the other way around. Moreover, to expand the front-side passage 20, after the front-side removable floor member 56 and the rear-side removable floor member 58 are removed from the pair of guide rails 32, the installation base 34 is moved to the side where the rear-side passage 22 is located and is brought into contact with the rear-side fixed floor member 54. That is, the installation base 34 is moved from the fixation position to the movement position on the other side (the rear side). As a result, the rack 16 supported on the installation base 34 is moved to the side where the rear-side passage 22 is located, and the front-side passage 20 is expanded. Then, the front-side removable floor member 56 and the rear-side removable floor member 58 are disposed side by side between the front-side fixed floor member 52 and the moved installation base 34, whereby the floor section 14A on the side where the front-side passage 20 is located is formed.

Next, the operation and the advantage of the first embodiment will be described.

As depicted in FIG. 2, in this embodiment, the pair of guide rails 32 is covered with the front-side fixed floor member 52, the rear-side fixed floor member 54, the front-side removable floor member 56, and the rear-side removable floor member 58. Moreover, the top face sections 52U, 54U, 56U, and 58U of the front-side fixed floor member 52, the rear-side fixed floor member 54, the front-side removable floor member 56, and the rear-side removable floor member 58 form the floor section 14A of the rack housing chamber 14.

As a result, when the rack 16 is carried into the rack housing chamber 14 through the carry-in entrance 24, since the pair of guide rails 32 does not pose an obstacle to the operator, the operator is kept from, for example, stumbling over the pair of guide rails 32. Moreover, the rack 16 is kept from coming off the installation base 34. Therefore, as compared to a case where the pair of guide rails 32 is exposed to the outside, the workability of carry-in operation of the rack 16 is improved.

Similarly, when the operation or the maintenance of the electronic devices 18 is performed from the front-side passage 20 and the rear-side passage 22, since the pair of guide rails 32 does not pose an obstacle to the operator, the operator is kept from, for example, stumbling over the pair of guide rails 32. Therefore, as compared to a case where the pair of guide rails 32 is exposed to the outside, the workability of maintenance and so forth performed by the operator is improved.

Moreover, the front-side fixed floor member 52, the rear-side fixed floor member 54, the front-side removable floor member 56, and the rear-side removable floor member 58 are disposed in such a way that the top faces thereof are flush with one another. As a result, the floor section 14A of the rack housing chamber 14 becomes flat. This stabilizes the footing of the operator and suppresses loss of screws and so forth that fix parts to the electronic devices 18 when the parts of the electronic devices 18 are replaced.

Furthermore, in this embodiment, by moving the installation base 34 along the pair of guide rails 32 in the manner described earlier, it is possible to expand the front-side passage 20 or the rear-side passage 22. This makes it possible to expand the operator's work space.

Moreover, for example, when an additional electronic device 18 is installed in the rack 16 or a part of the electronic device 18 is replaced, depending on the size of the electronic device 18 or the part, it may be difficult to carry in or out the part or replace the part from the front-side passage 20 and the rear-side passage 22. In such a case, by expanding the front-side passage 20 or the rear-side passage 22, it becomes easy to carry in or out the part or replace the part from the front-side passage 20 and the rear-side passage 22.

In addition, for example, when the rear-side passage 22 is expanded by moving the installation base 34 to the side where the front-side passage 20 is located, by disposing the front-side removable floor member 56 in a place where the installation base 34 was situated, the floor section 14A is formed in the expanded rear-side passage 22. Therefore, since the pair of guide rails 32 is not exposed to the outside also in the expanded rear-side passage 22, the operator's workability is further improved.

Furthermore, by fitting the front-side removable floor member 56 into the place where the installation base 34 was situated, the movement of the installation base 34 to the side where the rear-side passage 22 is located is restricted. As a result, for example, even when the container 12 sways during an earthquake, the movement of the racks 16 to the side where the rear-side passage 22 is located is restricted. This suppresses breakage or the like of the electronic devices 18. Moreover, for example, a situation in which the operator in the front-side passage 20 presses the rack 16 to move the rack 16 to the side where the rear-side passage 22 is located without noticing that there is another operator in the rear-side passage 22 is avoided.

Next, the second embodiment will be described. Incidentally, component elements whose structures are the same as the structures of the component elements of the first embodiment are identified with the same reference characters, and the descriptions thereof are omitted as appropriate.

As depicted in FIG. 1, the rack housing structure 60 is applied to the container 12. The rack housing structure 60 includes the racks 16, the movement mechanisms 30, partition members 76, and cable guides 92. The racks 16 are supported by the above-described movement mechanisms 30 movably in a direction in which the racks 16 move closer to and away from the rear wall section 12R of the container 12. Incidentally, the rear wall section 12R of the container 12 is an example of a wall section of a rack housing chamber.

As depicted in FIG. 2, in the rear wall section 12R of the container 12, a plurality of (in this embodiment, three) suction ports 62 for taking air in the rack housing chamber 14 are formed. The plurality of suction ports 62 are disposed side by side in a horizontal direction. Each suction port 62 is formed from a lower end portion of the rear wall section 12R to an intermediate portion of the rear wall section 12R. The racks 16 are disposed in such a way that the racks 16 face the suction ports 62 and the front-side openings 28F face the suction ports 62. Moreover, the height of each suction port 62 is assumed to be almost the same as the height of each rack 16.

In the rear wall section 12R of the container 12, a plurality of (in this embodiment, three) exhaust ports 64 for exhausting the air inside the rack housing chamber 14 to the outside are formed. The plurality of exhaust ports 64 are disposed side by side above the suction ports 62 in a horizontal direction.

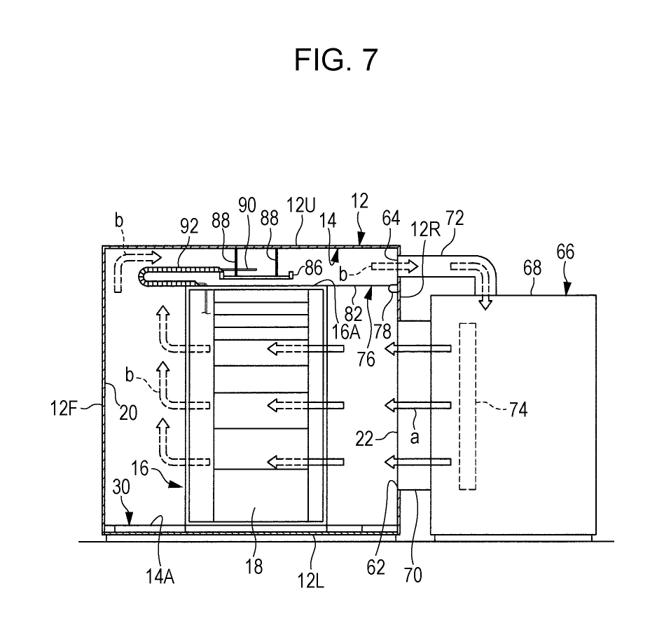

As depicted in FIG. 7, an air conditioning unit 66 that adjusts the temperature inside the rack housing chamber 14 is disposed next to the container 12. The air conditioning unit 66 is disposed on that side of the container 12 where the rear wall section 12R is located. The air conditioning unit 66 includes a unit main body 68, a suction duct 70, and an exhaust duct 72.

Inside the unit main body 68, a blower 74 that sends air into the rack housing chamber 14 is provided. The unit main body 68 is connected to the suction ports 62 of the rack housing chamber 14 via the suction duct 70. Moreover, the unit main body 68 is connected to the exhaust ports 64 of the rack housing chamber 14 via the exhaust duct 72. Incidentally, the unit main body 68 may be provided with a cooling device or the like that cools air that is sent into the rack housing chamber 14.

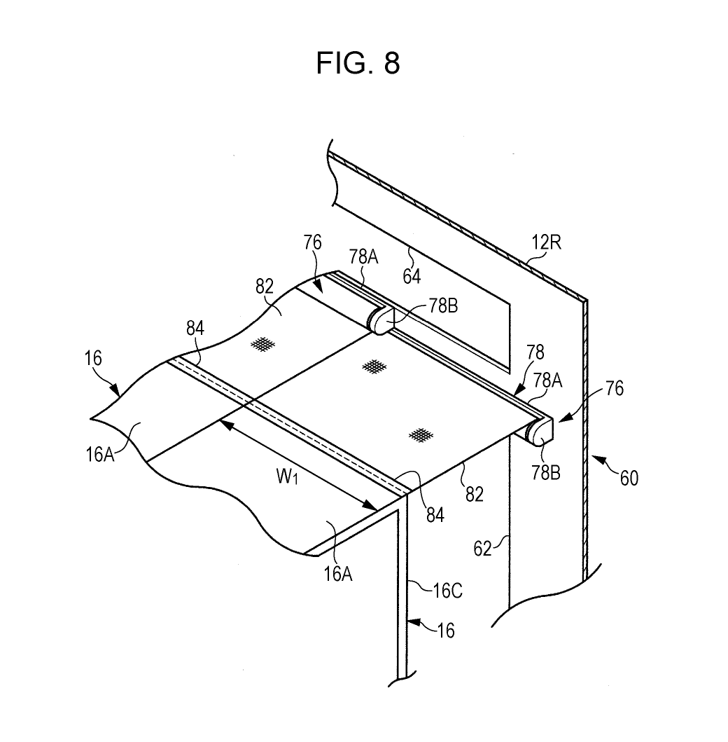

Furthermore, as depicted in FIG. 8, in the rack housing chamber 14, a plurality of (in this embodiment, seven) partition members 76 that vertically partition the front-side passage 20 between the suction ports 62 and the exhaust ports 64 are provided. The plurality of partition members 76 are disposed side by side in a horizontal direction between the suction ports 62 and the exhaust ports 64.

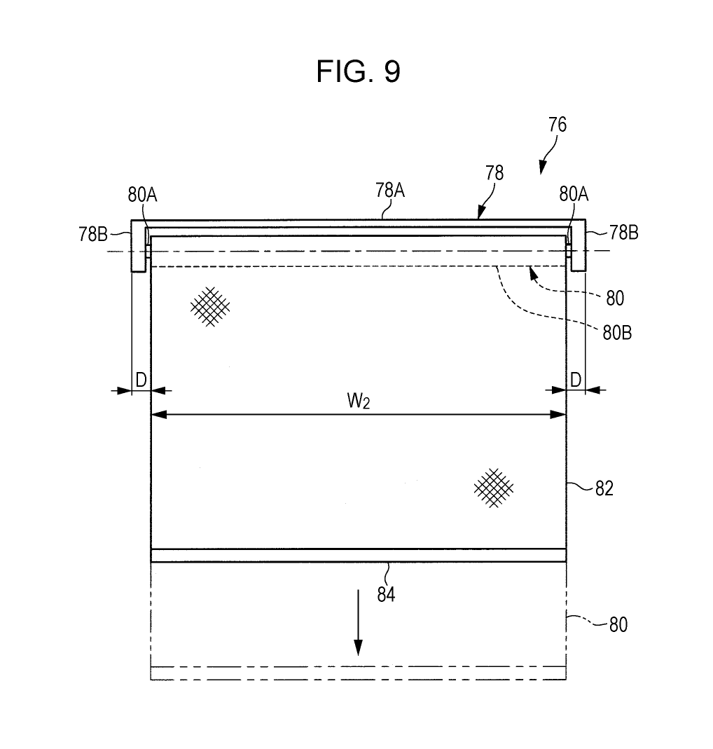

As depicted in FIG. 9, each partition member 76 has a base bracket 78, a rotation roll 80, and a partition sheet 82. The base bracket 78 is disposed in such a way that the longitudinal direction thereof coincides with a horizontal direction. The base bracket 78 has a fixed section 78A and a pair of bearing sections 78B. Incidentally, the partition sheet 82 is an example of a sheet-shaped section.

The fixed section 78A is fixed between the suction port 62 and the exhaust port 64 in the wall section with unillustrated screws or the like. At both ends of the fixed section 78A in the longitudinal direction thereof, the bearing sections 78B are provided. Each of the pair of bearing sections 78B extends from a corresponding end of the fixed section 78A to a side opposite to the rear wall section 12R. Between the pair of bearing sections 78B, the rotation roll 80 is disposed. Incidentally, the rotation roll 80 is an example of a winding section.

The rotation roll 80 has a shaft section 80A and a roll section 80B. In the shaft section 80A, both ends in an axial direction thereof are rotatably supported on the pair of bearing sections 78B. In an intermediate portion of the shaft section 80A in an axial direction thereof, the roll section 80B is provided.

The roll section 80B is formed into a cylindrical column, and the roll section 80B is disposed on the same axis as the shaft section 80A and is rotatable with the shaft section 80A. Moreover, the width W₂ of the roll section 80B is assumed to be the same as the width W₁ (see FIG. 8) of the rack 16. The partition sheet 82 is wound around the roll section 80B. Incidentally, the roll section 80B is biased by an unillustrated elastic body such as a spring at all times such that the roll section 80B rotates in a direction (a reeling-in direction) in which the partition sheet 82 is reeled in.

The partition sheet 82 is formed of a resin sheet material or the like that does not let air through. Moreover, the width of the partition sheet 82 is assumed to be the same as the width W₂ of the roll section 80B. One end of the partition sheet 82 is fixed to the roll section 80B with an adhesive or the like and is wound around the roll section 80B as a result of the roll section 80B being rotated in a predetermined direction (a reeling-in direction). The partition sheet 82 is reeled out from the roll section 80B as indicated with chain double-dashed lines as a result of the other end (the tip) being pulled. As a result, the partition sheet 82 is able to follow the movement of the rack 16.

As depicted in FIG. 8, at the other end of the partition sheet 82, a mounting bracket 84 is provided. By fixing the mounting bracket 84 in the top plate 16A (the top end) of the rack 16 with unillustrated screws or the like, the partition sheet 82 is disposed between the base bracket 78 and the rack 16. Incidentally, a method for fixing the partition sheet 82 to the rack 16 may be changed as appropriate.

Here, on both sides of the rotation roll 80, the pair of bearing sections 78B is disposed. Therefore, when the plurality of partition members 76 are arranged in such a way as to lie next to one another, if the rotation rolls 80 situated next to each other are disposed on the same axis, a gap that is twice as wide as a gap D (see FIG. 9) is formed between the partition sheets 82 situated next to each other. As measures against this, in this embodiment, the plurality of partition members 76 are alternately turned upside down and the bearing sections 78B situated next to each other are disposed in such a way that one bearing section 78B is vertically put over another such that the partition sheets 82 situated next to each other are disposed in such a way that one partition sheet 82 is put over another.

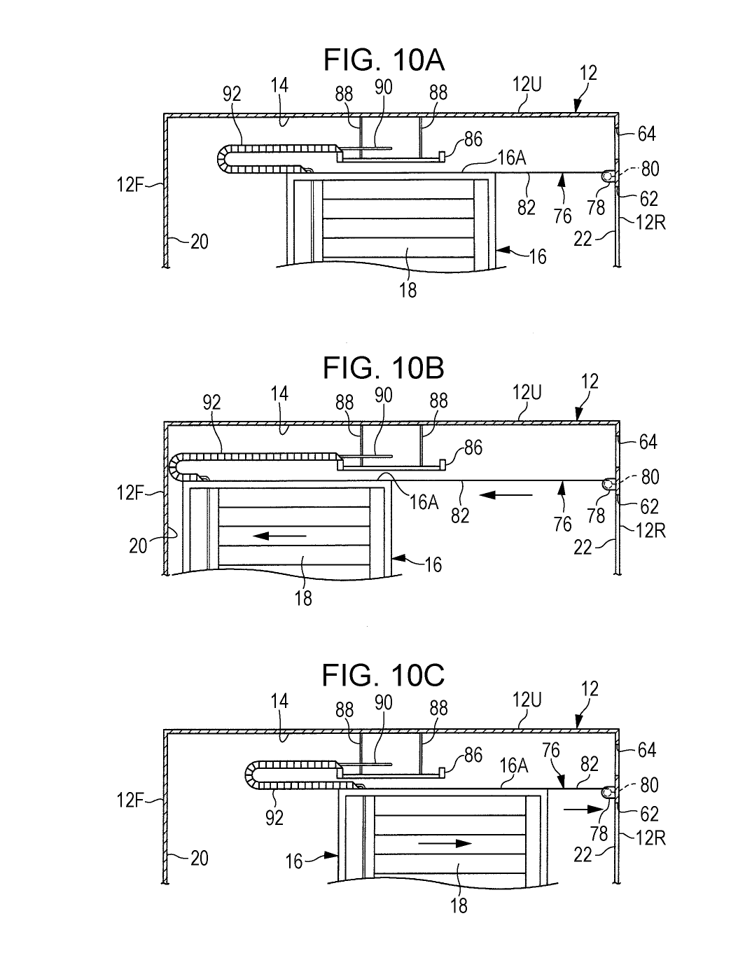

As depicted in FIG. 10A, above the rack 16, a cable rack 86 is disposed. The cable rack 86 is hung from the top wall section 12U of the container 12 by a hanging member 88 and supports the cable 90 that is routed to the rack 16. The cable rack 86 and the rack 16 are connected by the cable guide 92 curved in the shape of the letter U.

The cable guide 92 extends from the cable rack 86 to the front-side passage 20, and an intermediate portion thereof is bent downward and is connected to that side of the top plate 16A of the rack 16 where the front-side passage 20 is located. By passing the cable 90 through the cable guide 92, the cable 90 is guided to the rack 16 from the cable rack 86.

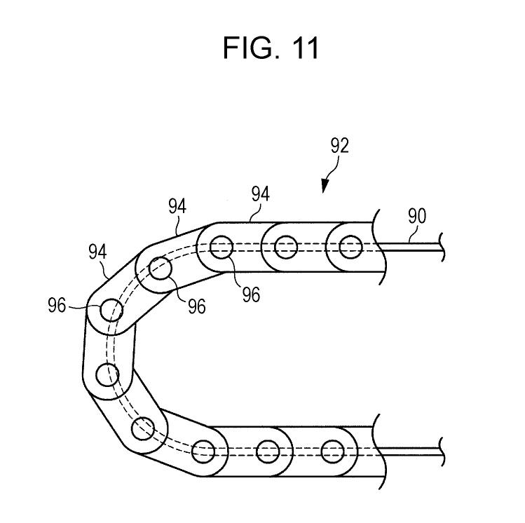

As depicted in FIG. 11, the cable guide 92 has a plurality of holding members 94 disposed in series. Each holding member 94 is formed into a hollow body having a rectangular cross section and allows the cable 90 to be inserted therethrough. Moreover, the holding members 94 situated next to each other are connected by connecting pins 96, each being an example of a rotating shaft, in such a way that the holding members 94 are able to perform relative rotation. This allows the cable guide 92 to bend freely.

Moreover, as depicted in FIGS. 10B and 10C, the length of the cable guide 92 is set at a length that allows the movement mechanism 30 to move the rack 16 to the side where the front-side passage 20 is located and the side where the rear-side passage 22 is located. Incidentally, in this embodiment, when the rack 16 is moved to the side where the front-side passage 20 is located, the rack 16 is in the position that is farthest away from the cable rack 86. Therefore, the length of the cable guide 92 is set in accordance with the distance between the cable rack 86 and the rack 16 when the rack 16 is moved to the side where the front-side passage 20 is located.

Next, the operation and the advantage of the second embodiment will be described.

First, the operation of the partition member 76 will be described.

As depicted in FIG. 7, between the suction port 62 and the exhaust port 64 in the rear wall section 12R of the container 12, the partition member 76 is provided. The partition sheet 82 is wound around the rotation roll 80 of the partition member 76. The partition sheet 82 is reeled out from the rotation roll 80, and the tip (the other end) thereof is fixed to the top plate 16A of the rack 16. As a result, the partition sheet 82 is disposed between the rear wall section 12R of the container 12 and the top plate 16A of the rack 16. With the partition sheet 82, the rear-side passage 22 is partitioned vertically between the suction port 62 and the exhaust port 64.

Therefore, when the blower 74 of the air conditioning unit 66 is actuated, as indicated with an arrow a, air is sent from the unit main body 68 to the rear-side passage 22 located below the partition sheet 82 via the suction duct 70 and the suction port 62. As a result of the air passing through the rack 16, the plurality of electronic devices 18 housed in the rack 16 are cooled.

Moreover, as indicated with an arrow b, the warm air warmed by the passage through the rack 16 moves upward along the front wall section 12F of the container 12 and is exhausted to the unit main body 68 via the exhaust duct 72 through the exhaust port 64 after passing over the rack 16 and the partition member 76.

As described above, by vertically partitioning the rear-side passage 22 by the partition sheet 82 between the suction port 62 and the exhaust port 64, the air (cold air) sent from the unit main body 68 to the front-side passage 20 and the warm air warmed by the passage through the rack 16 are kept from being mixed together. Therefore, the cooling efficiency of the electronic device 18 is improved.

Furthermore, the rotation roll 80 of the partition member 76 reels in or reels out the partition sheet 82 with the movement of the rack 16. Specifically, as depicted in FIG. 10B, when the rack 16 is moved by the movement mechanism 30 to the side where the front-side passage 20 is located, the partition sheet 82 is reeled out from the rotation roll 80. This suppresses breakage or the like of the partition sheet 82.

On the other hand, as depicted in FIG. 10C, when the rack 16 is moved by the movement mechanism 30 to the side where the rear-side passage 22 is located, the partition sheet 82 is reeled in by the rotation roll 80, whereby the deflection of the like of the partition sheet 82 is suppressed. As a result, the warm air and the cold air are kept from being mixed together via the gap between the partition sheets 82 situated next to each other.

As described above, in this embodiment, by making the partition sheet 82 follow the movement of the rack 16, it is possible to improve the cooling efficiency of the electronic devices 18 while suppressing breakage or the like of the partition sheet 82.

Next, the operation of the cable guide 92 will be described.

As depicted in FIG. 10A, the cable rack 86 and the rack 16 are connected by the cable guide 92. The cable guide 92 is bendable. Moreover, the length of the cable guide 92 is set at a length that allows the movement mechanism 30 to move the rack 16 to the side where the front-side passage 20 is located and the side where the rear-side passage 22 is located.

As a result, as depicted in FIGS. 10B and 10C, since the cable guide 92 does not block the movement of the rack 16 with respect to the cable rack 86, it is possible to move the rack 16 by the movement mechanism 30 to the side where the front-side passage 20 is located and the side where the rear-side passage 22 is located.

Moreover, by routing the cable 90 along the cable guide 92, the cable 90 has plenty of length for making it possible to move away the rack 16 from the cable rack 86. Therefore, as compared to a case where the cable guide 92 is not used, wiring of the cable 90 is performed more easily.

Furthermore, by passing the cable 90 through the cable guide 92, the deflection or the like of the cable 90 is suppressed when the rack 16 is moved with respect to the cable rack 86. Therefore, the cable 90 is kept from being caught between the cable rack 86 and the rack 16.

Next, modified examples of the above-described first and second embodiments will be described.

In the first embodiment described above, an example in which the installation base 34 is supported by the pair of guide rails 32 has been described, but an embodiment is not limited thereto. For example, a central part of the installation base 34 may be slidably supported by one guide rail 32, or the installation base 34 may be slidably supported by three or more guide rails 32.

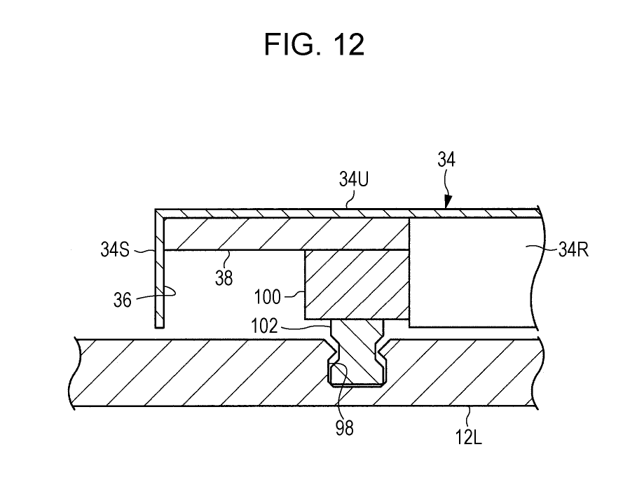

Moreover, as depicted in FIG. 12, in place of the pair of guide rails 32, a pair of guide groove sections 98 may be formed in the bottom wall section 12L of the container 12. Specifically, the pair of guide groove sections 98 extends in a movement direction of the installation base 34 and are parallel to each other. Incidentally, in FIG. 12, only one guide groove section 98 is depicted. Moreover, the guide groove section 98 is an example of the guide member.

On the other hand, on each side of the placement section 34U of the installation base 34 in the under surface thereof, a sliding member 102 is provided with the reinforcing panel 38 and a mount 100 placed between the under surface and the sliding member 102. By slidably engaging the sliding members 102 in the guide groove sections 98 (by bringing the sliding members 102 into engagement with the guide groove sections 98), the installation base 34 is movably supported along the guide groove sections 98.

In addition, in the first embodiment described above, an example in which the front-side removable floor member 56 and the rear-side removable floor member 58 are disposed on both sides (the front side and the rear side) of the installation base 34 and the installation base 34 is movable backward and forward has been described, but an embodiment is not limited thereto. The installation base 34 may be movable only to the front side or the rear side by disposing a removable floor member only on one side (the front side or the rear side) of the installation base 34.

Furthermore, in the first embodiment described above, an example in which the top face sections 52U, 54U, 56U, and 58U of the front-side fixed floor member 52, the rear-side fixed floor member 54, the front-side removable floor member 56, and the rear-side removable floor member 58 are formed into a panel has been described, but an embodiment is not limited thereto. The top face sections 52U, 54U, 56U, and 58U may be formed into a grid, for example. The same goes for the placement section 34U of the installation base 34.

In addition, in the first embodiment described above, an example in which the top face sections 52U, 54U, 56U, and 58U and the top face of the placement section 34U are flush with one another has been described, but an embodiment is not limited thereto. For example, a step may be provided between the top face sections 52U, 54U, 56U, and 58U and the placement section 34U.

Moreover, in the first embodiment described above, an example in which the front-side removable floor member 56 and the rear-side removable floor member 58 as the removable cover bases are disposed on the pair of guide rails 32, but an embodiment is not limited thereto. As the removable cover base, a protective cover base that protects the pair of guide rails 32 may be adopted.

Furthermore, in the first embodiment described above, an example in which the front-side fixed floor member 52 and the rear-side fixed floor member 54 as the stopper sections are provided on the pair of guide rails 32 has been described, but an embodiment is not limited thereto. The stopper section only has to be able to keep the installation base 34 from coming off the pair of guide rails 32. Therefore, for example, the stopper section such as an engaging pin that engages the installation base 34 and restricts the movement of the installation base 34 may be provided in the pair of guide rails 32. Moreover, the front wall section 12F and the rear wall section 12R of the container 12 may be used as the stopper sections.

In addition, in the first embodiment described above, an example in which the rack 16 is installed on the installation base 34 has been described, but an embodiment is not limited thereto. On the installation base 34, an object other than the rack 16 may be installed. That is, various objects to be supported may be installed on the installation base 34.

Moreover, in the second embodiment described above, an example in which the rear-side passage 22 is vertically partitioned by the partition members 76 has been described, but an embodiment is not limited thereto. For example, as the partition member, an accordion sheet material that is able to expand and contract like an accordion curtain may be used, or a plurality of slidably stacked sliding plates may be used.

Furthermore, in addition to the container 12, the first and second embodiments described above may be applied also to a server room and so forth in a building.

While the embodiments of the technique discussed above have been described, the technique discussed above is not limited to the above-described embodiments. Moreover, the above-described embodiments and various modified examples may be appropriately combined and used, and it goes without saying that the technique discussed above may be implemented in various ways without departing from the spirit of the technique discussed above.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A movement mechanism comprising:
a guide member;
an installation base that is movably provided on the guide member; and
a removable cover base that is removably disposed, next to the installation base, on the guide member.

2. The movement mechanism according to claim 1, further comprising:
a stopper section that is provided on the guide member and restricts a movement of the installation base; wherein
the removable cover base is disposed between the installation base and the stopper section.

3. The movement mechanism according to claim 1, wherein
the stopper section is provided on both sides of the installation base, and
the removable cover base is disposed between the installation base and the stopper sections on both sides of the installation base.

4. The movement mechanism according to claim 1, wherein
the removable cover base is a removable floor member that forms a floor section.

5. The movement mechanism according to claim 4, wherein
the stopper section is a fixed floor member that is provided on the guide member and forms the floor section with the removable floor member.

6. The movement mechanism according to claim 5, wherein
top faces of the removable floor member and the fixed floor member are flush with each other.

7. The movement mechanism according to claim 1, wherein
the guide member is a pair of guide rails facing each other, and
the installation base and the removable cover base are disposed on the pair of guide rails.

8. The movement mechanism according to claim 1, wherein
on the installation base, a rack that houses an electronic device is installed.

9. The movement mechanism according to claim 1, wherein
the guide member is provided in a floor section of a container that houses an electronic device.

10. A rack housing structure comprising:
a rack that is housed in a rack housing chamber having a suction port and an exhaust port in a wall section, the suction port and the exhaust port arranged vertically;
a movement mechanism that is provided in the rack housing chamber and moves the rack in a direction in which the rack moves closer to and away from the wall section; and
a partition member that is disposed between the wall section and the rack, vertically partitions a space between the wall section and the rack, and follows a movement of the rack.

11. The rack housing structure according to claim 10, wherein
the suction port is disposed below the exhaust port, and
the rack faces the suction port.

12. The rack housing structure according to claim 10, further comprising:
a blower that sends air into the rack housing chamber through the suction port.

13. The rack housing structure according to claim 10, wherein
the partition member includes
a sheet-shaped section that vertically partitions a space between the wall section and the rack and
a winding section around which the sheet-shaped section is wound, the winding section that reels in or reels out the sheet-shaped section with a movement of the rack.

14. The rack housing structure according to claim 10, wherein
the movement mechanism is the movement mechanism according to claim 1.

15. The rack housing structure according to claim 10, further comprising:
a cable rack that is disposed above the rack and supports a cable; and
a cable guide that movably connects the rack to the cable rack and guides the cable from the cable rack to the rack.

16. The rack housing structure according to claim 15, wherein
the cable guide has a plurality of holding members that are arranged in series and hold the cable, and
the holding members situated next to each other are connected in such a way that the holding members are able to perform relative rotation.

17. The rack housing structure according to claim 10, wherein
the rack houses an electronic device.

18. The rack housing structure according to claim 10, wherein
the rack housing chamber is formed in the container.
